(19) United States
(12) Patent Application Publication
(10) Pub. No.: US 2012/0032526 A1
(43) Pub. Date: Feb. 9, 2012

(54) Methods, Systems and Devices for Dissipating Kinetic Energy from Shock Waves with Electrical Loads

(75) Inventor: Ronald G. Lundgren, Littleton, CO (US)

(73) Assignee: APPLIED RESEARCH ASSOCIATES, INC., Albuquerque, NM (US)

(21) Appl. No.: 12/850,290

(22) Filed: Aug. 4, 2010

(51) Int. Cl. H03K 3/00

(52) U.S. Cl. 307/106

(57) ABSTRACT

Methods, systems and devices for dissipating kinetic energy from a shock wave are provided herein. In one embodiment, a method for dissipating kinetic energy from a shock wave may include: applying a magnetic flux across a shock wave disposed within a channel, wherein the channel includes substantially constant dimensions as the shock wave propagates through the channel; transforming kinetic energy from the shock wave to electrical energy; applying a high potential electrode to the electrical energy; applying a low potential electrode to the electrical energy; and coupling an electrical load conductively with the high potential electrode and the low potential electrode to dissipate the kinetic energy from the shock wave.

### TECHNICAL FIELD

The present specification generally relates to methods, systems and devices for energy conversion and, more specifically, to methods, systems and devices for dissipating kinetic energy from a shock wave.

### BACKGROUND

Energy is frequently generated and applied to various applications by converting one type of energy to another type of energy. For example, shields may dissipate kinetic energy and protect assets from the deleterious effect of explosively generated shock waves. Shields typically comprise robust and massive deflectors. The deflectors may be pre-emplaced heavy blast doors made of concrete, steel, or other shock absorbing materials. Such blast doors are subject to damage when utilized to deflect a shock wave and require maintenance before re-use. Additionally, due to their size and weight, heavy blast doors deploy slowly relative to the propagation rate of a shock wave generated by an explosion.

In addition to deflecting a shock wave, it may be desirable to intentionally generate the shock wave and utilize the shock wave as an energy source in lieu of other energy sources. For example, capacitors may convert electrical energy stored in batteries to high power microwave energy. The high power microwave energy may be utilized in various high power microwave systems such as, for example, radar imaging, communications, radar detection, and weapons that disable equipment and electronic devices. However, the batteries commonly require a large volume to produce enough power for the effective operation of the high power microwave systems. Effective operation may be facilitated by producing the necessary amount of power with a volume of explosive material that is smaller than the volume of the batteries by dissipating the energy of a shock wave generated by the explosive material with an electrical load.

Accordingly, a need exists for alternative methods, systems and devices for dissipating kinetic energy from a shock wave with electrical loads.

### SUMMARY

In one embodiment, a method for dissipating kinetic energy from a shock wave may include: applying a magnetic flux across a shock wave disposed within a channel, wherein the channel includes substantially constant dimensions as the shock wave propagates through the channel; transforming kinetic energy from the shock wave to electrical energy; applying a high potential electrode to the electrical energy; applying a low potential electrode to the electrical energy; and coupling an electrical load conductively with the high potential electrode and the low potential electrode to dissipate the kinetic energy from the shock wave.

In another embodiment, a system for dissipating kinetic energy from a shock wave may include: an electronic control unit including a processor and an electronic memory; a channel enclosing a fluid; a high potential electrode in contact with the fluid, wherein the high potential electrode includes an initiation surface; a low potential electrode in contact with the fluid, wherein the low potential electrode includes a termination surface facing the initiation surface; an electrical load conductively coupled to the high potential electrode and the low potential electrode; a north pole magnetic source communicatively coupled to the electronic control unit; and a south pole magnetic source communicatively coupled to the electronic control unit. The electronic control unit executes machine readable instructions to generate a magnetic flux across a shock wave propagating through the fluid, such that the magnetic flux induces an electric field between the initiation surface and the termination surface.

In yet another embodiment, a device for dissipating kinetic energy from a shock wave may include: a channel enclosing a fluid and defining a direction of propagation of a shock wave; a high potential electrode in contact with the fluid; a low potential electrode in contact with the fluid; a load conductively coupled to the high potential electrode and the low potential electrode; a north pole magnetic source coupled to the channel, wherein the north pole magnetic source includes a flux directing surface that faces the fluid; a south pole magnetic source disposed across from and substantially parallel to the north pole magnetic source, wherein a magnetic flux direction is substantially normal to the flux directing surface and substantially orthogonal to the direction of propagation; and an explosive, wherein a shock wave propagates along the direction of propagation upon a detonation of the explosive.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of a device for dissipating kinetic energy from a shock wave according to one or more embodiments shown and described herein;

FIG. 2A schematically depicts an exploded view of a device for dissipating kinetic energy from a shock wave according to one or more embodiments shown and described herein;

FIG. 2B schematically depicts an exploded view of a device for dissipating kinetic energy from a shock wave according to one or more embodiments shown and described herein;

FIG. 3 schematically depicts a system for dissipating kinetic energy from a shock wave according to one or more embodiments shown and described herein;

FIG. 4 schematically depicts a perspective view of a device for dissipating kinetic energy from a shock wave according to one or more embodiments shown and described herein;

FIG. 5 schematically depicts an exploded view of a device for dissipating kinetic energy from a shock wave according to one or more embodiments shown and described herein;

FIG. 6 schematically depicts a system for dissipating kinetic energy from a shock wave according to one or more embodiments shown and described herein; and

FIG. 7 graphically depicts the results of a mathematic model of a device for dissipating kinetic energy from a shock wave according to one or more embodiments shown and described herein.

### DETAILED DESCRIPTION

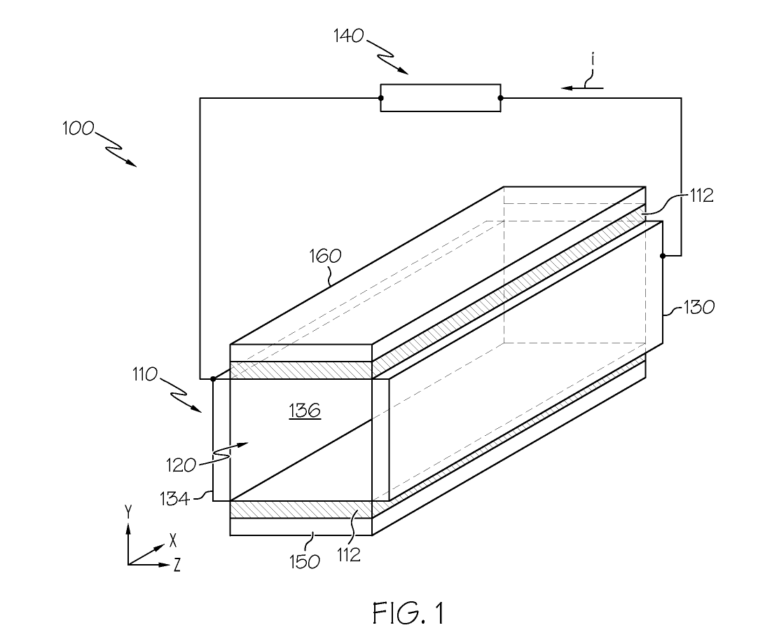

FIG. 1 generally depicts one embodiment of a device for dissipating kinetic energy from a shock wave with an electrical load. The device generally comprises a channel enclosing a fluid, magnetic sources such as, for example, permanent magnets capable of producing 1 tesla, electrodes such as, for example, high conductivity copper electrodes, and an electrical load. Various embodiments of the device, as well as methods and systems for dissipating kinetic energy from a shock wave with an electrical load will be described in more detail herein.

Referring now to FIG. 1, an embodiment of a device 100 for dissipating the kinetic energy from a shock wave (not shown in FIG. 1) is depicted. The device 100 generally comprises a channel 110 enclosing a fluid 120, a north pole magnetic source 150, a south pole magnetic source 160, a high potential electrode 130, a low potential electrode 134, and an electrical load 140. It is noted that, while the electrical load 140 is depicted as being connected to the high potential electrode 130 and the low potential electrode 134 at particular locations, the electrical load 140 may be connected to the high potential electrode 130 and the low potential electrode 134 at any location that provides for conductive coupling. That is, provided that the electrodes 130, 134 are conductively coupled, the specific spatial location of the conductive coupling is arbitrary. Furthermore it is noted that, while the north pole magnetic source 150, the south pole magnetic source 160, the high potential electrode 130, and the low potential electrode 134 are depicted as extending the full length of the channel 110, in the embodiments described herein the north pole magnetic source 150, the south pole magnetic source 160, the high potential electrode 130, and the low potential electrode 134 may each extend a partial length of the channel 110.

The channel 110 is a structure, tunnel, or adit that defines an outer boundary of an at least partially enclosed fluid 120 and constrains the motion of the fluid 120 such that the motion can be guided along one direction. In one embodiment, the channel 110 comprises a rectangular cross-section that is formed by insulators 112, a high potential electrode 130 and a low potential electrode 134. However, it is noted that the channel 110 may comprise any shape as a cross-section such as, for example, a circle, an oval, a polygon, a natural shape, or an irregular shape. Additionally it is noted, the channel 110 is generally depicted in FIGS. 1-2B and 4-5 as comprising a constant cross-section for clarity and not by limitation. Thus, the channel 110 may comprise a varying cross-section that, according to the specific aerodynamic properties the varying cross-section, may enhance or diminish the transformation of shock wave kinetic energy to electrical energy. The channel 110 may be formed of any material that can be configured to maintain substantially constant dimensions when subjected to the traverse of a shock wave such as, for example, a metal, a hardwood, plastic, concrete or a natural stone. For example, the channel 110 may withstand a shock wave traverse that is intentionally generated by an explosive energy and/or a shock wave traverse generated by an explosive energy that can be anticipated such as, but not limited to, a high density explosive within a metal tube, an explosive detonated in a subway tunnel by a terrorist, or an accidental detonation of an incendiary material in a mining tunnel. The channel 110 may be any length, or distance along the direction of propagation x, i.e., for rapid energy conversion the length may be on the order of about an inch and for slower energy conversion the length may be on the order of many feet or much larger. Furthermore, it is noted that any of the elements described herein may be disposed within the channel 110, rather than being integral with the channel 110.

Furthermore, it is noted that the channel 110, as described herein, may be formed of any of the elements described herein that are capable of forming a fluidic boundary that is robust enough to contain and allow for the propagation of a shock wave within the bounded fluid. Therefore, by maintaining “substantially constant dimensions,” the channel is rigid enough to collimate the shock wave. Collimation assists in the transformation of shock wave kinetic energy to electrical energy by maintaining the kinetic energy within the shock front while it passes through a magnetic field. For the purpose defining and describing the present disclosure, it is noted that the term “fluid” as used herein means a substance, such as a liquid or a gas, that is capable of flowing and that changes its shape when acted upon by a force tending to change its shape. Thus, the embodiments described herein may be especially useful to protect assets from exterior events designed to collimate and project a shock wave toward the asset. An example is the detonation of explosives within an opened door of a subway car that collimates and projects a shock wave towards passengers at a loading station.

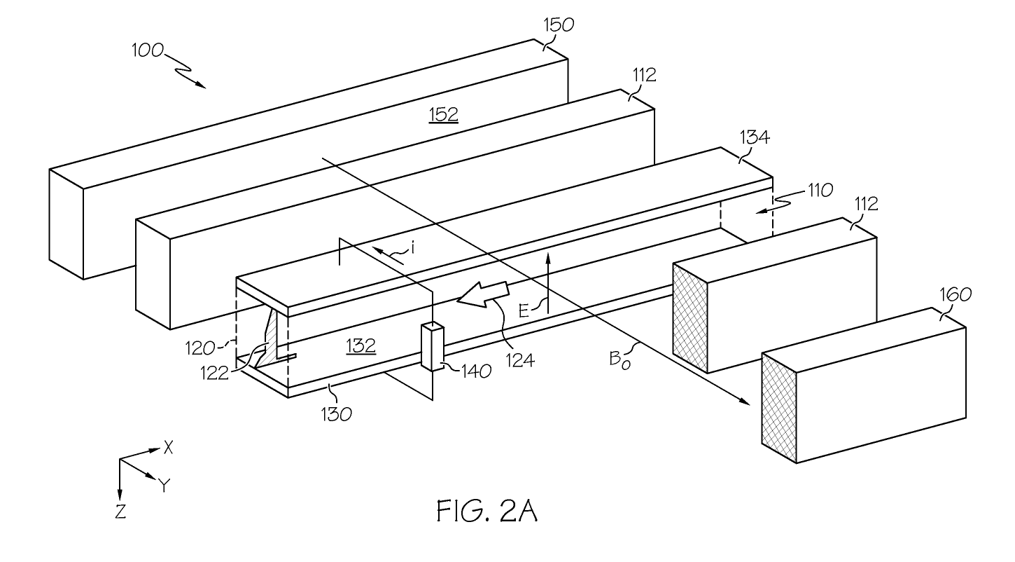

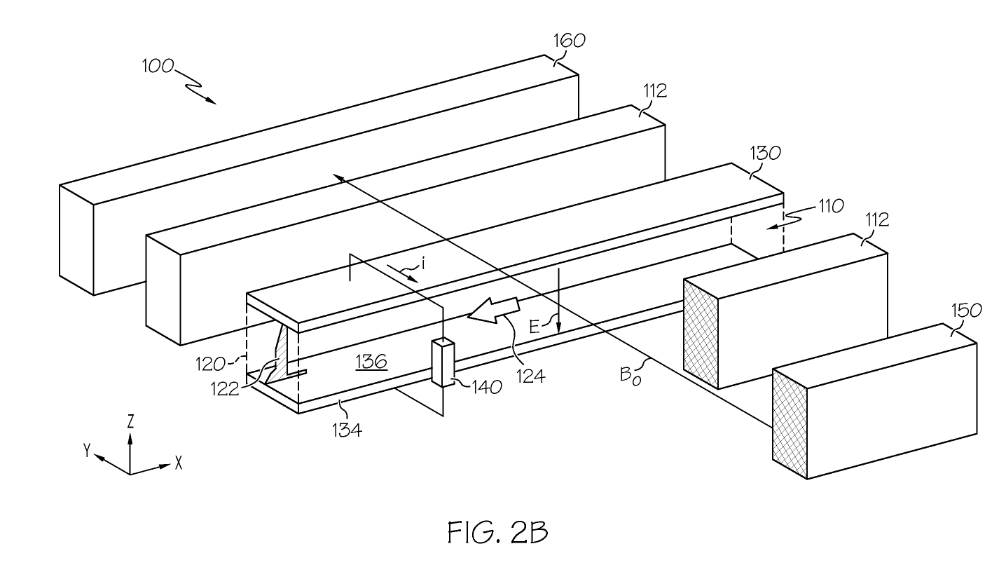

The magnetic sources 150, 160 generate magnetic fields across the fluid 120. Referring now to FIG. 2A, in one embodiment of the device 100, the north pole magnetic source 150 and the south pole magnetic source 160 are disposed on opposite sides of the channel 110. The magnetic fields originate at the north pole magnetic source 150 and terminate at the south pole magnetic source 160. Therefore, a magnetic flux density B₀ can impinge on the fluid 120 when the shock wave 122 is disposed between the magnetic sources 150, 160. The magnetic sources 150, 160 may be permanent magnets, electromagnets, or a combination thereof. As used herein, the term “permanent magnet” means a magnetized object that generates a persistent magnetic field. The term “electromagnet,” as used herein, means an electrically powered object that generates a magnetic field in relation to the amount of power consumed by the object.

Referring now to FIGS. 2A and 2B, the electrodes 130,134 are conductive objects capable of maintaining electrical surface charges. In one embodiment, an electric field E is transmitted across the fluid 120 from an initiation surface 132 of the high potential electrode 130 to a termination surface 136 of the low potential electrode 134. The electrodes 130,134 may comprise any material suitable for conducting electricity, such as copper, gold or any known or yet to be discovered conductive material. The electrodes 130, 134 may also comprise any shape such that they are configured to make electrical contact with the fluid 120. While the high potential electrode 130 and the low potential electrode 134 are depicted as rectangular plates, the electrodes 130,134 may comprise any other shape that does not interfere with the magnetic flux density B₀ and provides electrical contact between a surface of the electrodes 130,134 and the fluid 120 such as, for example, a curved plate, a disk, a sheet, a sphere, and the like. Thus, the electrodes 130,134 need not be identical and/or parallel.

Referring again to FIG. 1, an electrical load 140 may receive electrical current i from the high potential electrode 130 and the low potential electrode 134. Specifically, in one embodiment the electrical load 140 is conductively coupled to the high potential electrode 130 and the low potential electrode 134. The electrical load 140 may comprise any type of electrical circuit that transfers energy to do mechanical, electrical, electromagnetic, acoustic or thermodynamic work. Therefore, the electrical load 140 may convert electrical energy into various forms such as, for example, heat, light, motion, sound or electromagnetic fields. It is noted that the term “conductively coupled,” as used herein, means electrical communication via a conductive mechanism such as for example, terminal blocks, posts, solder joints, integrated circuit traces, wires, and the like.

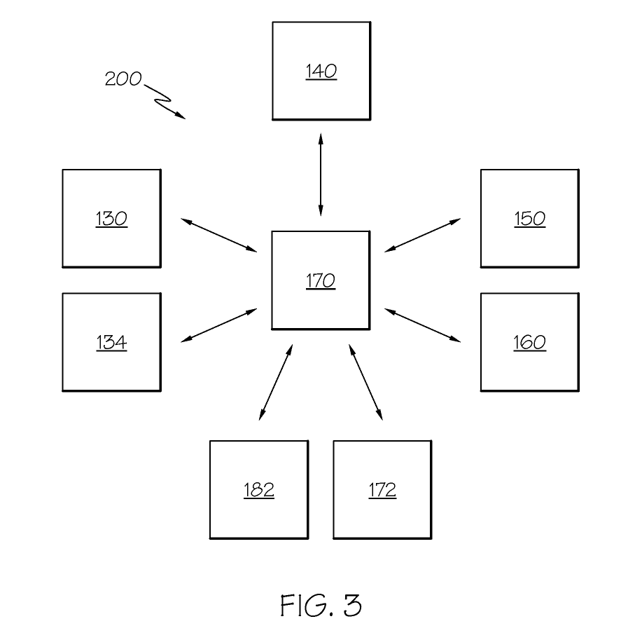

Referring now to FIG. 3, an embodiment of a system 200 for dissipating kinetic energy from a shock wave 122 (FIG. 2A) with an electrical load 140 is schematically depicted. In one embodiment, the system 200 comprises a plurality of modules that are communicatively coupled to the electronic control unit 170. Specifically, the electronic control unit 170 may be coupled to the high potential electrode 130, the low potential electrode 134, the electrical load 140, the north pole magnetic source 150, the south pole magnetic source 160, the shock sensor 172, and the detonator 182. Embodiments of the system 200, described herein, may include all or some of the modules. The modules not previously described will be described in further detail hereinafter.

The electronic control unit 170 comprises a processor for executing machine readable instructions and a memory for electronically storing machine readable instructions and machine readable information. The processor may be an integrated circuit, a microchip, a computer or any other computing device capable of executing machine readable instructions. The memory may be RAM, ROM, a flash memory, a hard drive, or any device capable of storing machine readable instructions. In the embodiments described herein, the processor and the memory are integral with the electronic control unit 170. However, it is noted that the processor and the memory may be discrete components communicatively coupled to one another such as, for example, modules distributed throughout the system 200 without departing from the scope of the present disclosure. Furthermore, it is noted that the phrase “communicatively coupled,” as used herein, means that components are capable of transmitting data signals with one another such as, for example, electrical signals via a conductive medium, electromagnetic signals via air, optical signals via optical waveguides, and the like.

The shock sensor 172 is a device for measuring indicia of a shock or explosive event. In one embodiment, the shock sensor 172 senses the indicia and transmits a signal indicative of the shock or explosion to the electronic control unit 170. For example, the shock sensor 172 may sense an overpressure and transmit information indicative of the overpressure to the electronic control unit 170. Embodiments of the shock sensor 172 may measure indicia of a shock or explosion such as, for example, light, temperature, pressure, ionization, and the like. It is noted that the term “sensor,” as used herein, means a device that measures a physical quantity and converts it into an electrical signal, which is correlated to the measured value of the physical quantity, such as, for example a transducer, a transmitter, an indicator, a piezometer, a manometer, an accelerometer, and the like. Furthermore, the term “signal” means an electrical waveform, such as DC, AC, sinusoidal-wave, triangular-wave, square-wave, and the like, capable of traveling along a conductive medium.

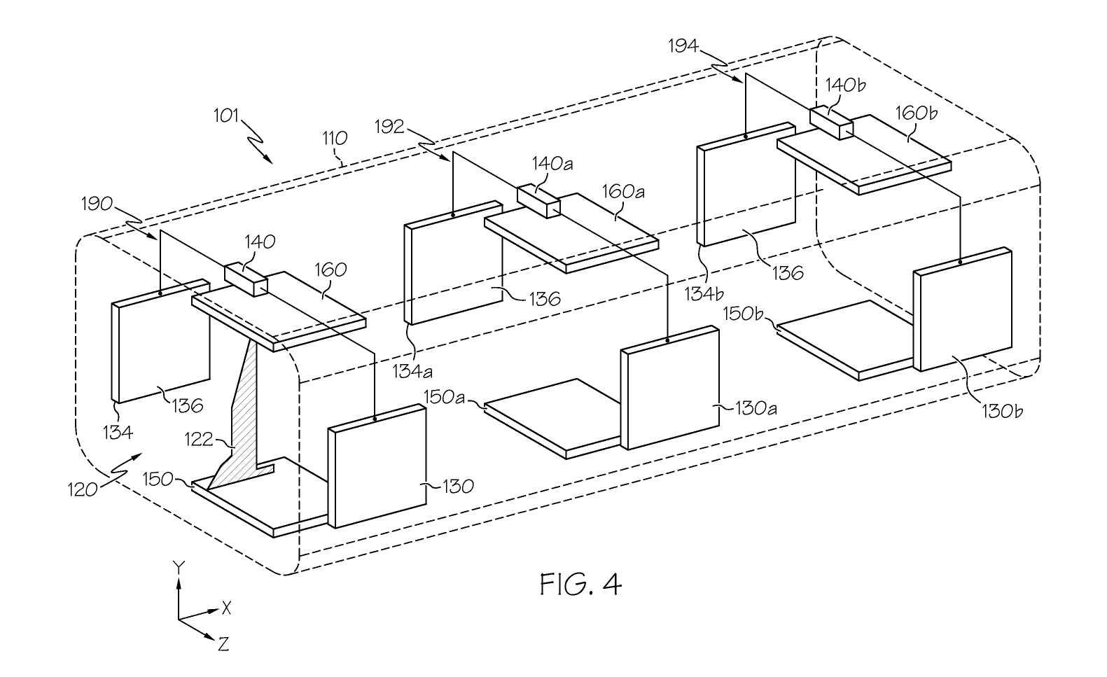

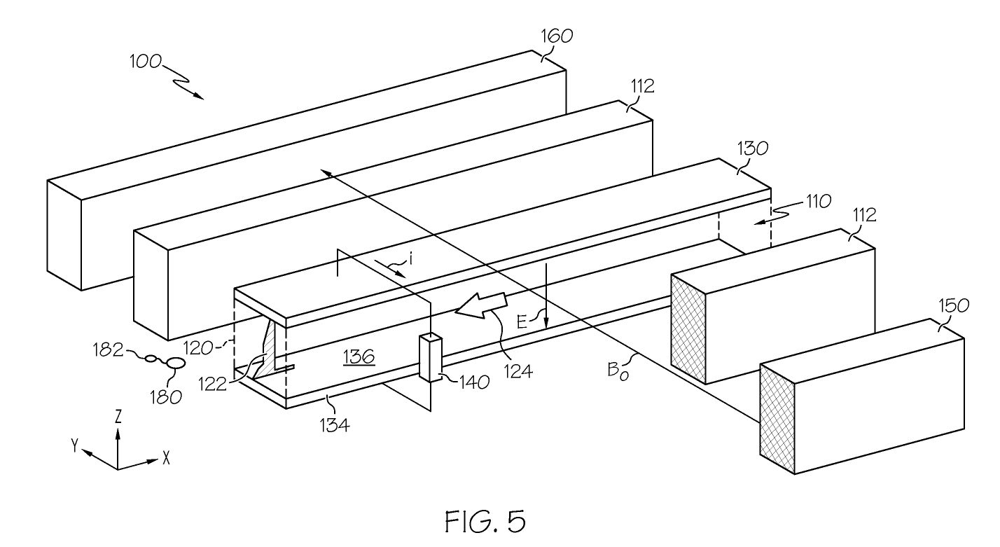

Referring now to FIG. 4, the detonator 182 is a device that comprises a chemical, mechanical, or electrical mechanism for triggering the explosion of the explosive 180. The explosive 180 (FIG. 5) is a substance that comprises stored energy that may produce a rapid expansion of gas detonation products accompanied by the production of light, heat, pressure, and combinations thereof. A detonation velocity may be utilized to categorize the explosive 180. The detonation velocity is the velocity with which the explosive process propagates throughout the mass of the explosive 180. For example, mining explosives may have detonation velocities ranging from about 1,800 m/s to about 8,000 m/s. In some embodiments, the system 200 may comprise an explosive 180 with a known detonation velocity such as, but not limited to, a polymer bonded explosive (e.g., LX14 with a detonation velocity of about 9,000 m/s) or any other high density, high velocity material. In other embodiments, the system 200 may comprise an explosive 180 with an unknown detonation velocity. For example, an improvised explosive device (IED), comprising any pyrotechnic, incendiary, or explosive material, may be detonated as a result of rogue activity. Therefore, in the embodiments described herein, the explosive 180 may comprise any material capable of generating a lethal shock wave 122.

A shock wave 122 will be generated by the detonation of the explosive 180. For example, the detonation may initiate a driving pressure that is greater than a hundred atmospheres and increase the temperature to an ionizing temperature. The driving pressure and the ionizing temperature serve as sources of kinetic energy that cooperate to form the shock wave 122. The shock wave 122 may be dense (on the order of about several hundred micrometers thick) and may travel along a direction of propagation x within a fluid 120 disposed within the channel 110 at a high velocity. The high velocity is a function of the driving pressure (i.e., the higher the driving pressure, the higher the velocity) and may be from about 1 km/s to about 25 km/s for conventional explosives. However, it is noted that the embodiments described herein may operate with explosives with higher driving pressure such as, for example, non-conventional explosives or explosions produced extra-terrestrially. As the shock wave 122 forms a pressure discontinuity, or shock front, the ionizing temperature forms a sheet-like ionized zone of several mean free paths of the detonation product at the shock front. The ionized zone comprises free charge and forms a thin conductive zone, which is analogous to a conductor traveling with the shock wave 122. The system 200 contains high kinetic energy, which may be utilized to power an electrical load 140 according to the embodiments described herein.

A magnetic curtain can be erected to dissipate the kinetic energy from the shock wave 122 relatively rapidly via the electrical load 140 when the channel length is relatively short such as a window well or a door frame. Referring again to FIGS. 2A-3, the system 200 may comprise a channel 110 surrounding a fluid 120, insulators 112, a high potential electrode 130, a low potential electrode 134, an electrical load 140, a north pole magnetic source 150 and a south pole magnetic source 160. Specifically, in one embodiment, the high potential electrode 130 comprises an initiation surface 132 that is in fluidic communication with the fluid 120. The low potential electrode 134 comprises a termination surface 136 in fluidic communication with the fluid 120 and substantially parallel to the initiation surface 132. The electrical load 140 is conductively coupled to the high potential electrode 130 and the low potential electrode 134. The north pole magnetic source 150 is coupled to the channel 110 and comprises a flux directing surface 152 such that the magnetic flux direction y is substantially normal to the flux directing surface 152. The south pole magnetic source 160 is disposed across from and substantially parallel to the north pole magnetic source 150. The electrodes 130, 134 and the magnetic sources 150, 160 are electrically separated, so as not to short out the system, by insulators 112. The insulators 112 may comprise any volumetric shape. Additionally, it is noted that the term “insulator,” as used herein, means a material that resists the flow of electric current and separates conductive materials such as, for example, air, a dielectric, concrete, glass, porcelain, polymers, and the like.

A magnetic flux density B₀ can be generated between north pole magnetic source 150 and a south pole magnetic source 160 to fill a portion of the fluid 120 in front of the shock wave 122 to form a magnetic curtain. As the ionized shock front of the shock wave 122 impinges on the magnetic flux density B₀ along the direction of propagation x, kinetic energy from the shock wave 122 is converted to electrical energy as an electric field density E. The electric field density E is generated along the electric field direction (depicted in FIGS. 2A and 2B as the negative z direction) and current i flows through the electrical load 140. The current i produces a Lorentz Force 124 that opposes the direction of propagation x and reduces the kinetic energy of the shock wave 122. The Lorentz Force 124 and the current i flowing through the electrical load 140 reduces the driving pressure behind the shock wave 122 and the temperature of the shock wave 122. As the shock wave 122 progresses through the magnetic flux B₀ its kinetic energy is reduced on the time scale of the speed of light until the shock front becomes de-ionized. This recombination of electrons and molecules reflects the temperature decrease and the system ultimately stalls. Since only a minimum amount of conductivity need be present to maintain the system (less than about 100 mhos/meter) the magnetic flux density B₀ or device 100 geometry may be configured to stall when the shock wave 122 reaches a sub-lethal energy level.

An exemplary mathematical model describing the conversion of the kinetic energy from the shock wave 122 may be formulated by combining a model describing fluid dynamics with adjustments from a model describing electrodynamics. Specifically, the mathematical model may be utilized for analytic computations by considering: the conservation of mass, the conservation of momentum, the conservation of energy, and the gas state equations. From the conservation of mass it may be inferred that the matter that goes into a plane fully exits the plane. From the conservation of momentum it may be inferred that the velocity drop and accompanying momentum change must be transferred to an electron particle and charged molecule. From the conservation of energy it may be inferred that the kinetic energy decrease as result of retardation of plasma velocity must be made up by the increase in electrical and/or joule heating energy. And finally, the gas state equations provide a relationship between temperature, pressure and volume. Thusly, the mathematical model may be solved for pressure, temperature, plasma velocity, and density to provide a descriptive tool regarding plasma deceleration as a function of channel length or flow down a channel when given material properties, initial conditions, and boundary conditions. It is noted that the exemplary mathematical models described herein are provided for clarity, and should not be interpreted as limiting or requiring the present disclosure to any particular theory. Therefore, the exemplary mathematical models are merely descriptive of the physical phenomena inherent to the embodiments described herein.

The stall point, or critical velocity, is a free variable that sets a threshold velocity at which the shock wave 122 must traverse along the direction of propagation x in order to dissipate kinetic energy from the shock wave 122 via the electrical load 140. The critical velocity is a term that is equal to the ratio of the electric field density E to the magnetic flux density B₀:

$$CriticalVelocity = \frac{E}{{B}_{0}}$$

Therefore, the critical velocity may be set by modifying the magnetic flux B₀ of the system in accordance with the electric field density E. In one embodiment, the electric field density E may be sensed or calculated real time and the magnetic flux can be altered via, for example, modifying the current supplied to an electromagnet. In another embodiment, the critical velocity may be designed into the physical dimensions of the system (e.g., adjusting the surface area of the electrodes 130, 134), the energy level of the explosion, or combinations thereof. Furthermore, it is noted that while the embodiments described herein are provided in relation to an x-y-z coordinate system, the arrangement of the elements of the embodiments described herein are to be interpreted as arranged in relation to one another and not to any fixed coordinate system.

The magnetic curtain may be utilized as a reusable magnetic blast shield that protects assets from the deleterious effects of shock waves. For example, if a rogue explosive event such as, but not limited to, the detonation of an IED, occurs within a subway tunnel which acts as a channel 110, a shock sensor 172 may sense an over pressure or an explosive flash indicative of the presence of a shock wave 122. The shock sensor 172 can transmit a signal indicative of the presence of the shock wave 122 to the electronic control unit 170. Then, a magnetic flux density B₀ can be generated between north pole magnetic source 150 and a south pole magnetic source 160 away from the shock wave 122. Since electrons travel at the speed of light, the sensing of the shock wave 122 and initiation of the magnetic flux density B₀ occurs prior to any significant movement of the shock wave 122 down the channel 110 and along the direction of propagation x. As the shock wave 122 travels along the direction of propagation x and orthogonally intersects with the magnetic flux B₀, current flows through the electrical load 140 via the electrodes 130,134. Kinetic energy is dissipated from the shock wave 122 via a Lorentz Force 124 and electrical energy dissipated by the electrical load 140.

Additionally, since the shock wave 122 maintains an ionized state due to the ionizing temperature, the shock front will maintain its conductivity until the kinetic energy of the shock wave 122 becomes sub lethal, i.e. ionization is correlated with high temperature and pressure of the shock wave which may cause lethal effects for both personnel and equipment. A reduction in the shock front ionization has a commensurate reduction in lethality. Specifically, lack of ionization (i.e., stalling the system) may be accompanied by reduction in driving pressure and temperature of the shock wave such that a human sub-lethal environment would be created. For example, if a shock wave was generated by the detonation of an explosive in a subway tunnel, passengers in the tunnel would experience a very high wind, but not a collapse of their chest cavity, or production of free radicals within their biological system.

In one embodiment of the device 101, depicted in FIG. 4, the electrical energy dissipation of the electrical load 140 may be accomplished by heat dissipation into the surrounding structure. The electrodes 130,134 that collect charge and drain kinetic energy from the shock wave 122 can be embedded plates installed in segments down the channel 110. For example, the embedded plates may be physically and electrically attached to reinforcing steel of a subway tunnel. The reinforcing steel acts as the electrical load 140, and operates as a resistor that converts electrical current into heat. Additional resistive loads can be created by utilizing conductive objects within the concrete structure of the tunnel such as, for example, mounting hardware, rebar, reinforcements, and the like. Due to the large volume of dense material within a subway tunnel such as, for example, concrete, a large amount of heat may be dissipated from the shock wave 122. Therefore, a reusable magnetic blast shield may be formed to transform a destructive shock wave 122 into a non-damaging event. Further embodiments may be installed in mining tunnels, window frames, door frames, or any other structure comprising a channel-like structure.

In another embodiment, the electrical load 140 may comprise a circuit for generating an electromagnetic transmission. For example, the transmission power level can be scaled to the energy level of shock event giving instantaneous annunciation of rogue activity, and the level of threat. Since, the shock wave 122 powers the transmission circuit, no additional power source is required to signal the occurrence of rogue activity.

Still referring to FIG. 4, permanent magnet seeds may be used in a device 101 that is segmented to feed energy to power other elements of the device 101. The device 101 may comprise multiple segments 190,192, 194 each capable of reducing the kinetic energy of a shock wave 122. The first segment 190 comprises electrodes 130, 134, magnetic sources 150, 160, and an electrical load 140. The second segment 192 comprises electrodes 130a, 134a, magnetic sources 150a, 160a, and an electrical load 140a. The third segment 194 comprises electrodes 130b, 134b, magnetic sources 150b, 160b, and an electrical load 140b. For example, the first segment 190 may comprise an electrical load 140 conductively coupled to the north pole magnetic source 150a of the second segment 192, the south pole magnetic source 160a of the second segment 192 or a combination thereof. As the shock wave 122 travels along the direction of propagation x, the shock wave 122 traverses the first segment 190 and then the second segment 192. The electrical load 140 of the first segment 190 is powered as the ionized shock front passes over the magnetic sources 150, 160 of the first segment 190, which are permanent magnet seeds. The electrical load 140 may then power the magnetic sources 150a, 160a of the second segment 192 as the shock wave 122 traverses the second segment 192. Similarly, the electrical load 140 may also be conductively coupled to the north pole magnetic source 150b of the third segment 194, the south pole magnetic source 160b of the third segment 194 or a combination thereof. Thusly, permanent magnets may be used as seeds to power the magnetic sources 150a, 160a, 150b, 160b of other segments either alone or in combination. Further embodiments of the device 101 may comprise any number of segments, and any type of electrical load 140 described herein. Therefore, it is contemplated that a single segmented device may convert the kinetic energy of the shock wave 122 into multiple types of energies.

Referring now to FIG. 5, embodiments of the device 100 may comprise a detonator 182 coupled to an explosive 180 for generating electrical power for high power directed energy transmissions. The high power directed energy transmission may be high powered microwaves, x-rays, sonar, lasers, emergency communication systems, or any other electrically powered transmission disposed within the electrical load 140. Any of the high power directed energy transmissions can be powered by a shock wave 122 impinging upon a magnetic flux density B₀, as described hereinabove.

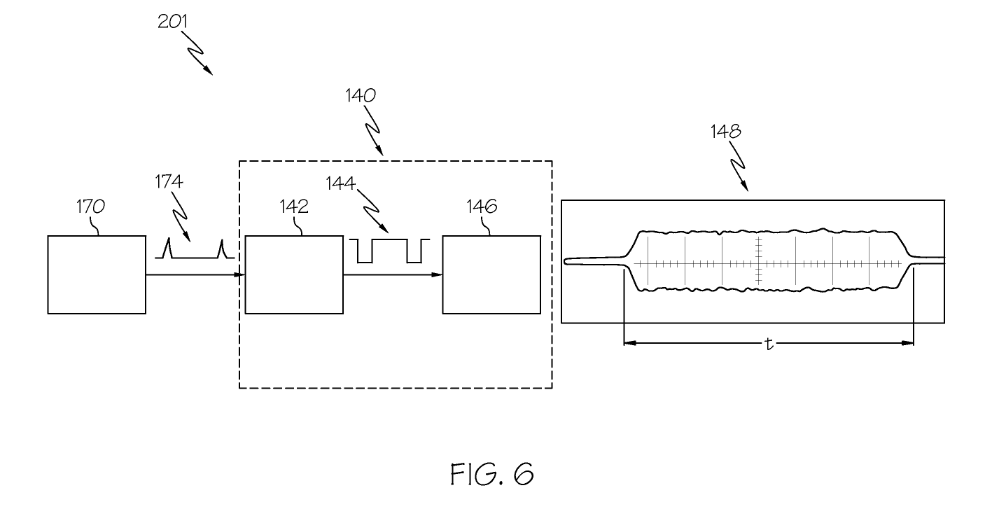

An embodiment of the system 201 for generating high power directed energy transmissions is depicted in FIGS. 5 and 6. The system 201 may provide a supply of electrical power to the electrical load 140 for the transmission of a high power microwave pulse 148. The high power microwave pulse 148 can be generated by conductively coupling an electrical load 140 comprising a pulse forming network to the electrodes 130, 134. The pulse forming network may comprise a modulator 142 conductively coupled to an oscillator 146, for example a magnetron. In one embodiment, the electronic control unit 170 causes the detonator 182 to detonate the explosive 180 yielding a shock wave 122 that travels along the direction of propagation x. The control signal 174 is coordinated with the shock wave 122 by, for example, timing the explosion or sensing the shock wave 122 with the electronic control unit 170. A control signal 174 is transmitted by the electronic control unit 170 to the modulator 142 to trigger the conversion of the current i into high voltage pulses 144. The modulator 142 receives the current i and transmits the high voltage pulses 144 to the oscillator 146. As a result, the oscillator 146 transmits a high power microwave pulse 148 with a pulse width of time t. In another embodiment, the oscillator 146 may be directly connected to the electrodes 130,134 without a modulator 142 to generate a continuous high power microwave.

High power microwaves with power densities of greater than about 10⁸ w/m³, such as, for example, power densities of about 10¹¹ w/m³ or greater, can be produced from systems with a size of about 0.001 m³. Similarly, systems that generate about 15,000 J can be produced in packages with a cross-section of less than about 0.1 m² with a length less than about 0.5 m. The high energy density allows the embodiments described herein to be suitable for many delivery systems that provide for extended standoff from a target such as, for example, rockets, missiles, or bombs. Therefore, the embodiments disclosed herein may be used as a power source for many applications associated with high power microwaves. For example, the embodiments described herein may be utilized as electromagnetic weapons, annunciation systems, early warning systems, and radar systems, such as, for example, bi-static targeting or bi-static imaging.

The embodiments described herein will be further clarified by the following example.

The embodiments described herein were analytically tested against theoretical solutions to shock waves propagating in a one-dimensional channel of nearly constant area. This allowed for the exploration of the shock wave structure and the extent of the effect of the electromagnetic field on the velocity and dynamic pressure behind the blast wave. The shock wave was computed over the detonation products mean free paths of thickness and the fluid assumed to be a conducting perfect gas that satisfies the standard compressible flow equations. The computation was run to simulate both a shock wave modified with an applied magnetic flux and a shock wave without an applied magnetic flux. The system was formulated by the partial differential equations of conservation of mass, momentum and energy. The state laws were utilized to close the system so that the number of variables equaled the number of equations. Finally, computer integrations were performed to describe a shock front jump over the thickness of the front for a theoretical system with a cross section of 0.0025 m², a channel length of 0.5 m, a constant Mach number of 19, a specific heat ratio of 1.25, a magnetic flux density of 2.1 Wb/m², an electric field density of 7,750 v/m, and a critical velocity of about 3.5 km/s.

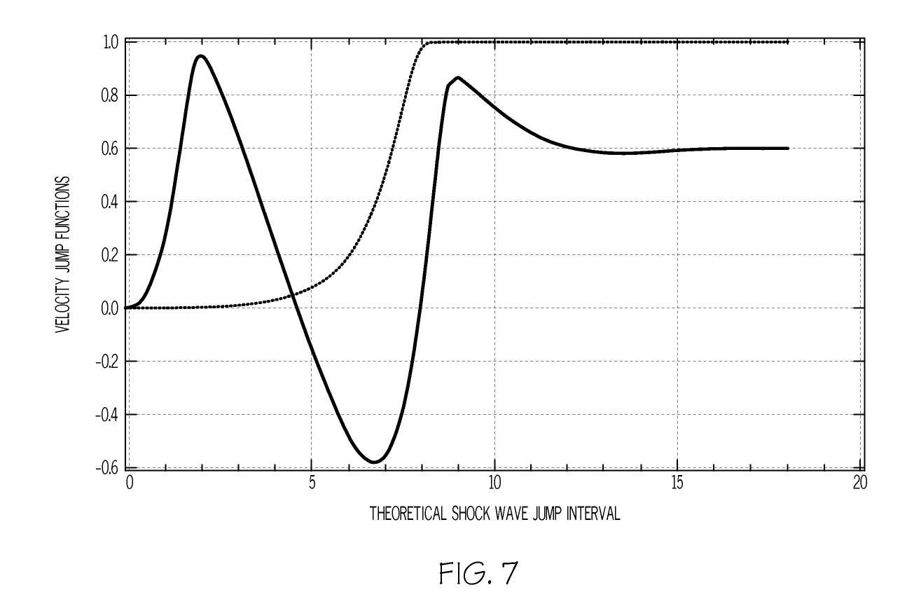

The results of the analysis are schematically depicted in FIG. 7, where the dashed line represents a shock wave without a magnetic flux applied and the solid line represents a shock with a magnetic flux applied. The units of the vertical axis are velocity jump functions normalized across the jump interval. The units of the horizontal axis are theoretical shock wave jump intervals that are indicative of the mean free paths of the combustion products. The steady state jump function was normalized to 1 for the shock wave without a magnetic flux applied and about 0.59 for the shock with a magnetic flux applied. Such a difference between the steady state jump functions correspond to a decrease in dynamic pressure of about 36% of the input. Therefore, the results confirmed the efficacy of the embodiments described herein and the practicality of setting a critical velocity for causing the system to stall at a sub-lethal velocity.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue. Furthermore, these terms are also utilized herein to represent the degree by which a quantitative representation may vary from a stated reference due to manufacturing tolerances or fabrication tolerances.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A method for dissipating kinetic energy from a shock wave, the method comprising:
applying a magnetic flux across a shock wave disposed within a channel, wherein the channel comprises substantially constant dimensions as the shock wave propagates through the channel;
transforming kinetic energy from the shock wave to electrical energy;
applying a high potential electrode to the electrical energy;
applying a low potential electrode to the electrical energy; and
coupling an electrical load conductively with the high potential electrode and the low potential electrode to dissipate the kinetic energy from the shock wave.

2. The method of claim 1 further comprising sensing a formation of the shock wave.

3. The method of claim 1 further comprising detonating an explosive to form the shock wave.

4. The method of claim 1 further comprising detecting a shock wave energy, and scaling the magnetic flux based upon the shock wave energy.

5. The method of claim 1 further comprising emitting a high powered directed energy from the electrical load.

6. The method of claim 1 further comprising emitting heat from the electrical load.

7. The method of claim 1 further comprising:
applying a second magnetic flux across the shock wave;
applying a second high potential electrode to the electrical energy;
applying a second low potential electrode to the electrical energy; and
coupling a second electrical load conductively with the second high potential electrode and the second low potential electrode to dissipate the kinetic energy from the shock wave.

8. The method of claim 7 wherein the second magnetic flux is powered by the electrical load.

9. A system for dissipating kinetic energy from a shock wave, the system comprising:
an electronic control unit comprising a processor and an electronic memory;
a channel enclosing a fluid;
a high potential electrode in contact with the fluid, wherein the high potential electrode comprises an initiation surface;
a low potential electrode in contact with the fluid, wherein the low potential electrode comprises a termination surface facing the initiation surface;
an electrical load conductively coupled to the high potential electrode and the low potential electrode;
a north pole magnetic source communicatively coupled to the electronic control unit; and
a south pole magnetic source communicatively coupled to the electronic control unit, wherein the electronic control unit executes machine readable instructions to generate a magnetic flux across the shock wave propagating through the fluid, such that the magnetic flux induces an electric field between the initiation surface and the termination surface.

10. The system of claim 9 further comprising a shock sensor disposed within the fluid and communicatively coupled to the electronic control unit, wherein the electronic control unit executes machine readable instructions to sense the shock wave.

11. The system of claim 9 further comprising an explosive, wherein the electronic control unit executes machine readable instructions to detonate the explosive such that the shock wave is generated.

12. The system of claim 11 wherein the explosive is a polymer-bonded explosive.

13. The system of claim 9 wherein the channel comprises substantially constant dimensions as the shock wave is generated and is propagated through the fluid.

14. The system of claim 9 wherein the electrical load comprises a resistive circuit, a pulse forming circuit, an oscillating circuit or a combination thereof.

15. A device for dissipating kinetic energy from a shock wave, the device comprising:
a channel enclosing a fluid and defining a direction of propagation of the shock wave;
a high potential electrode in contact with the fluid;
a low potential electrode in contact with the fluid;
a load conductively coupled to the high potential electrode and the low potential electrode;
a north pole magnetic source coupled to the channel, wherein the north pole magnetic source comprises a flux directing surface that faces the fluid;
a south pole magnetic source disposed across from and substantially parallel to the north pole magnetic source, wherein a magnetic flux direction is substantially normal to the flux directing surface and substantially orthogonal to the direction of propagation; and
an explosive, wherein a shock wave propagates along the direction of propagation upon a detonation of the explosive.

16. The device of claim 15 wherein:
the high potential electrode comprises an initiation surface in contact with the fluid;
the low potential electrode comprises a termination surface substantially parallel to the initiation surface; and
an electric field direction is substantially normal to the initiation surface, substantially orthogonal to the direction of propagation, and substantially orthogonal to the magnetic flux direction.

17. The device of claim 15 wherein the channel comprises substantially constant dimensions for withstanding a traverse of the shock wave due to the detonation of the explosive.

18. The device of claim 15 wherein at least one of the north pole magnetic source and the south pole magnetic source comprise a permanent magnet.

19. The device of claim 15 wherein at least one of the north pole magnetic source and the south pole magnetic source comprise an electromagnet.

20. The device of claim 15 wherein the load comprises a pulse forming circuit, an oscillating circuit or a combination thereof.
